(19) United States
(12) Patent Application Publication
(10) Pub. No.: US 2011/0180785 A1
(43) Pub. Date: Jul. 28, 2011

(54) TRANSISTOR STRUCTURE COMPRISING A CHEMICAL ADDITIVE, A DISPLAY AND AN ELECTRONIC APPARATUS

(76) Inventors: Christoph Wilhelm Sele, London (GB); Kevin Michael O'Neill, Eindhoven (NL); Nicolaas Aldegonda Jan Maria van Aerle, Eindhoven (NL)

(21) Appl. No.: 12/694,949

(22) Filed: Jan. 27, 2010

(51) Int. Cl. H01L 51/10

(52) U.S. Cl. 257/40; 977/735; 257/E51.003

(57) ABSTRACT

A transistor structure is described herein that includes a semiconductor layer and a dielectric layer. In accordance with the disclosure, at least one of the semiconductor layer and/or the dielectric layer comprises a chemical additive having a higher reaction potential for a chemical species present in an environment than a material of the semiconductor layer and/or the dielectric layer.

### FIELD

The invention relates to a transistor structure, in particular to a thin film transistor (TFT). More in particular, the invention relates to a display comprising a transistor structure. Still more in particular, the invention relates to an electronic apparatus comprising said display.

### BACKGROUND OF THE INVENTION

A transistor structure, in particular a thin film transistor structure (TFT) is described in US 2006/0273302. The known thin film transistor structure is coated with a barrier layer for counteracting adverse environmental effects such as exposure to light, oxygen and/or moisture. The barrier layer of the known thin film transistor structure comprises a polymer, an antioxidant, and an inorganic particulate material. The barrier layer is deposited during a manufacturing process of the known thin film transistor structure, which is arranged in contact with a semiconductor layer of the known TFT.

### SUMMARY OF THE INVENTION

It is a disadvantage of the known TFT structure that, in order to mitigate possible adverse environmental effects on the TFT structure, an additional processing step is necessitated. Such additional processing step may add complexity to the manufacturing logistics and increase costs of the manufacturing process. In addition, in some circumstances the semiconductor layer may already degrade before the barrier layer is deposited.

Illustrative embodiments provide a TFT structure which can be easily manufactured yet have improved resistance to environmental factors, like specific chemical species and/or to other characteristics, like humidity and/or light.

To this end a TFT structure is disclosed herein that comprises a semiconductor layer and a dielectric layer. Furthermore at least one of the semiconductor layer and/or a dielectric layer comprises a chemical additive. More particularly, the chemical additive has a higher reaction potential for a chemical species present in an environment than a material of the semiconductor layer and/or the dielectric layer.

By integrating a suitable chemical additive rendering an environmental chemical species inactive in the semiconductor layer and/or in the dielectric layer, an improved transistor structure is provided. It will be appreciated that the chemical additive is conceived to increase chemical resistivity or other properties regarding an environmental element which may have a detrimental effect on performance of the TFT structure. For example, the environmental element may relate to a gas constituent or to liquid. For example the gas may be oxygen, water vapor, ozone, nitrous oxide, carbon monoxide, while the liquid may be water. It is found that the transistor structure disclosed herein has improved properties related to environmental stability, and that degradation of the semiconductor layer and/or the dielectric layer immediately post deposition is counteracted. This feature reduces degradation during suitable subsequent processing steps, without the need for processing to be carried out under a protective atmosphere. In addition, the transistor structure according to the invention is compatible with low-cost processing, which may lead to elimination of costly vapor deposition steps.

A display according to the invention comprises a transistor structure as is set forth in the foregoing. In a particular embodiment, the transistor structure forms part of a flexible carrier enabling manufacturing of a flexible display.

An electronic apparatus according to the invention comprises the display according to the foregoing.

These and other aspects of the invention will be set forth with reference to the figures wherein like reference signs relate to like elements. It will be appreciated that the figures are discussed for explanatory purposes only and may not be used for limiting the scope of the appended claims.

### BRIEF DESCRIPTION OF THE DRAWINGS

While the claims set forth the features of the present invention with particularity, the invention, together with its objects and advantages, may be best understood from the following detailed description taken in conjunction with the accompanying drawing of which:

FIG. 1 schematically presents an embodiment of a TFT structure according to the invention;

FIG. 2 schematically presents a further embodiment of a TFT structure according to the invention; and

FIG. 3 schematically presents an embodiment of an electronic apparatus according to the invention.

### DETAILED DESCRIPTION OF THE DRAWINGS

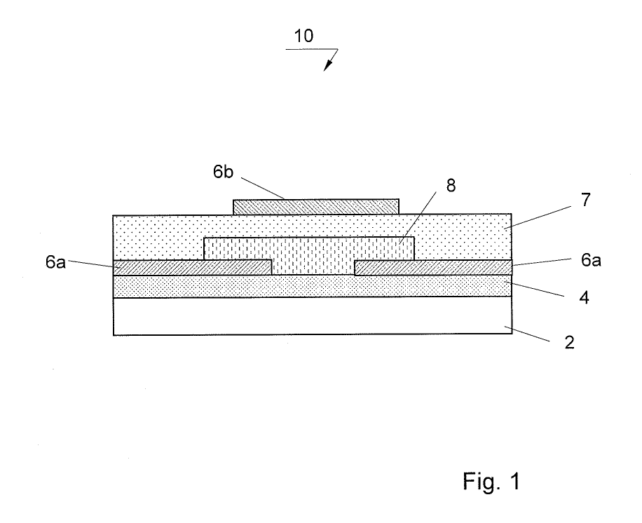

FIG. 1 presents a schematic view of a TFT structure 10 according to an embodiment of the invention. In this particular embodiment a TFT stack comprises a carrier foil 2 superposed with a barrier layer 4, which is followed by a first metal layer 6a, an organic semiconductor layer 8, a dielectric layer 7 and a second metal layer 6b. It will be appreciated that a transistor stack is formed at least by the layers 6a, 8, 7 and 6b, which has a top-gate architecture. In accordance with the invention any one of the following layers—the barrier layer 4, the semiconductor layer 8, or the dielectric layer 7 may include a chemical additive having a higher reaction potential for an environmental element than the materials constituting said layers.

The chemical additive may relate to an anti-oxidant, a stabilizer, an anti-aging agent or the like, as is, for example, explained with reference to the foregoing. The chemical agent may be homogeneously distributed in any of the named layers, or it may have an increased concentration at one of the interfaces with respect to further layers. For example, a surface of a layer provided with the chemical additive facing the environment may have an increased concentration of the chemical additive. Alternatively or additionally, a surface facing another layer in the TFT structure may have an increased concentration of the chemical additive. Finally, it is possible that both surfaces of a layer in a stack direction have an increased concentration of the chemical additive while a bulk concentration of said agent is kept substantially low.

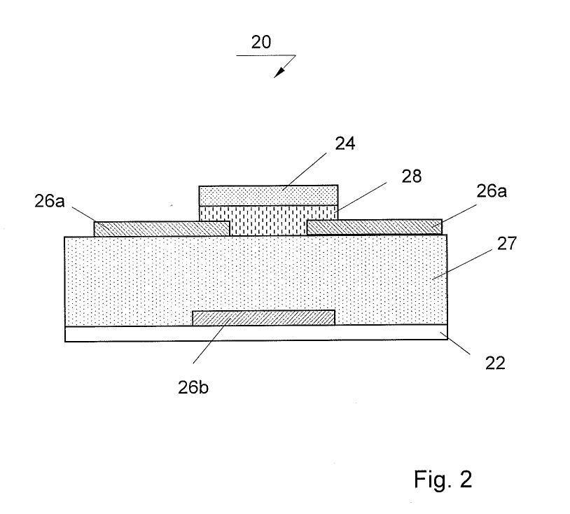

FIG. 2 presents a schematic view of a further illustrative embodiment in the form of a TFT structure 20. In this embodiment a carrier foil 22 is covered with a gate electrode 26b followed by a dielectric layer 27 on top of which an organic semiconductor layer 28 is provided, which is cooperating with source and drain electrodes 26a. The organic semiconductor layer is covered with a barrier (passivation) layer 24. The TFT stack relates to a bottom gate TFT architecture. Also in the embodiment depicted in FIG. 2, any of the layers 24, 28 or 27 includes a chemical additive having a higher reaction potential for an environmental element than respective materials of said layers. The chemical additive may relate to an anti-oxidant or a water scavenging agent.

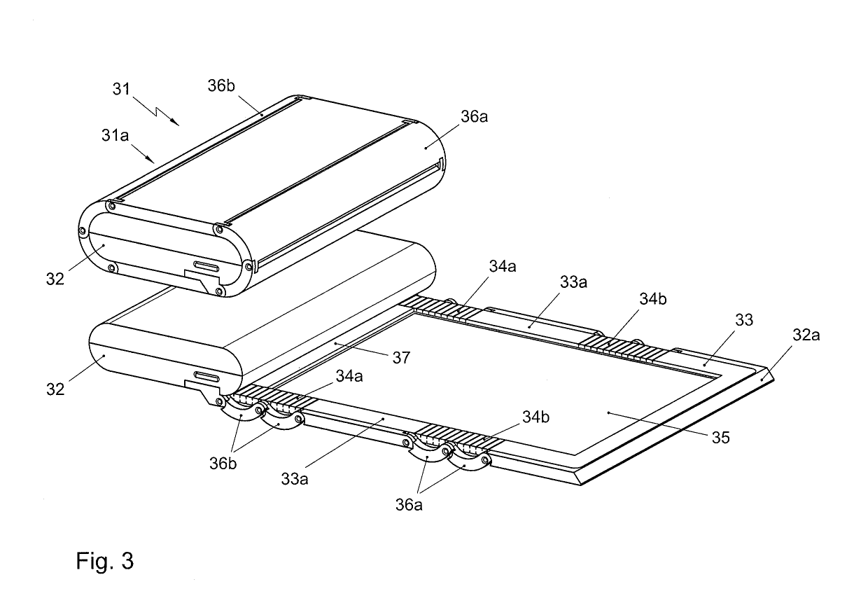

FIG. 3 illustratively presents an electronic apparatus 31 comprising a semiconductor device according to an illustrative embodiment of the invention. The electronic apparatus 31 comprises a housing 32 and a retractable, notably wrappable, flexible display 35 arranged on a rigid cover 32a. The display 35 is based on active driving technology wherein a display effect layer comprises electrophoretic capsules. The driving circuit is based on the TFT structures according to the embodiments disclosed herein, as is discussed with reference to FIGS. 1, 2. A rigid cover 32a is arranged to be wound together with the flexible display 35 around the housing 32 to a position 31a. The rigid cover 32a may comprise an edge member 33 provided with rigid areas 33a and flexible areas 34a, 34b cooperating with hinges 36a, 36b of the cover 32a. When the flexible display 35 is retracted to a position wound about the housing 32, the surface of the flexible display 35 abuts the housing 32. Functioning of the flexible display 35 is based on the integrated circuits comprising a substrate and a suitable chip bonded to the substrate. The bonding area is schematically indicated by 37. It will be appreciated that the electronic device comprising the flexible display is arranged for storing the flexible display in a housing of the electronic apparatus rolled about a suitable roller. Rollable electronic displays are known in the art and they are also based on integrated circuits comprising TFT structures. It is possible that rollable electronic displays are based on TFT structures as discussed with reference to FIGS. 1, 2. It will be appreciated that the electronic apparatus also comprises a rigid display based on TFT structures, as is discussed with reference to FIGS. 1, 2.

It will be appreciated that although specific illustrative embodiments of the structure according to the invention are discussed separately for clarity purposes, interchangeability of compatible features discussed with reference to isolated figures is envisaged. While specific embodiments have been described above, it will be appreciated that the invention may be practiced otherwise than as described. The descriptions above are intended to be illustrative, not limiting. Thus, it will be apparent to one skilled in the art that modifications may be made to the invention as described in the foregoing without departing from the scope of the claims set out below.

What is claimed is:

1. A transistor structure comprising:
a semiconductor layer; and
a dielectric layer,
wherein at least one of the semiconductor layer and/or the dielectric layer comprises a chemical additive having a higher reaction potential for a chemical species present in an environment than a material of the semiconductor layer and/or the dielectric layer.

2. The transistor structure according to claim 1, wherein the semiconductor layer is covered with a barrier layer, the chemical additive being included in the barrier layer.

3. The transistor structure according to claim 1, wherein the chemical additive is taken from the group of additives comprising: an anti-oxidant, an oxidation retarder, a scavenger, a stabilizer, a desiccant, or a combination thereof.

4. The transistor structure according to claim 2, wherein the chemical additive is taken from the group of additives comprising: an anti-oxidant, an oxidation retarder, a scavenger, a stabilizer, a desiccant, or a combination thereof.

5. The transistor structure according to claim 4, wherein the anti-oxidant is selected from the group comprising: butylated hydroxytoluene, fullerenes or derivatives thereof or a derivative of benzophenone or triazine.

6. The transistor structure according to claim 5, wherein the anti-oxidant comprises a soluble derivative of C60 or C70 fullerene or a mixture of soluble derivatives of C60 and C70 fullerenes.

7. The transistor structure according to claim 3, wherein the anti-oxidant comprises a polymer.

8. The transistor structure according to claim 4, wherein the anti-oxidant comprises a polymer.

9. The transistor structure according to claim 1, wherein the chemical additive has an increased concentration substantially in a surface region of the semiconductor layer and/or the dielectric layer conceived to interact with the environment.

10. The transistor structure according to claim 2, wherein the chemical additive has an increased concentration substantially in a surface region of the semiconductor layer and/or the dielectric layer conceived to interact with the environment.

11. The transistor structure according to claim 3, wherein the chemical additive has an increased concentration substantially in a surface region of the semiconductor layer and/or the dielectric layer conceived to interact with the environment.

12. The transistor structure according to claim 4, wherein the chemical additive has an increased concentration substantially in a surface region of the semiconductor layer and/or the dielectric layer conceived to interact with the environment.

13. The transistor structure according to claim 1, wherein the semiconductor layer comprises an organic material.

14. The transistor structure according to claim 2, wherein the semiconductor layer comprises an organic material.

15. The transistor structure according to claim 3, wherein the semiconductor layer comprises an organic material.

16. The transistor structure according to claim 4, wherein the semiconductor layer comprises an organic material.

17. The transistor structure according to claim 1, wherein the semiconductor layer comprises a binder.

18. The transistor structure according to claim 2, wherein the semiconductor layer comprises a binder.

19. The transistor structure according to claim 3, wherein the semiconductor layer comprises a binder.

20. The transistor structure according to claim 4, wherein the semiconductor layer comprises a binder.

21. The transistor structure according to claim 18, wherein the binder includes the chemical additive.

22. The transistor structure according to claim 21, wherein the binder comprises a co-polymer acting as an anti-oxidant.

23. The transistor structure according to claim 1, wherein the structure is a thin film transistor (TFT).
